(19) United States
(12) Patent Application Publication
(10) Pub. No.: US 2015/0075981 A1
(43) Pub. Date: Mar. 19, 2015

(54) ROTATING MAGNETRON SPUTTERING TARGET AND CORRESPONDING MAGNETRON SPUTTERING DEVICE

(71) Applicant: Hao Kuo, Guangdong (CN)

(72) Inventor: Hao Kuo, Guangdong (CN)

(73) Assignee: SHENZHEN CHINA STAR OPTOELECTRONICS TECHNOLOGY CO. LTD., Guangdong (CN)

(21) Appl. No.: 13/635,623

(22) PCT Filed: Jun. 14, 2012
(86) PCT No.: PCT/CN12/76876

§ 371 Date: Sep. 17, 2012

(30) Foreign Application Priority Data
Jun. 8, 2012 (CN) 201210187715.3

(51) Int. Cl. H01J 37/34; C23C 14/35

(52) U.S. Cl. CPC H01J 37/3405; H01J 37/3452; H01J 37/3423; C23C 14/35; H01J 2237/332
USPC 204/298.11; 204/298.22

(57) ABSTRACT

The present invention relates to a rotating magnetron sputtering target and a corresponding magnetron sputtering device. The rotating magnetron sputtering target comprises a cylindrical target, a pole shoe and a plurality of magnetrons. The magnetron comprises a first magnetic pole arranged on a central portion thereof and two second magnetic poles arranged on both sides thereof, and the first and the second magnetic poles have opposite polarities. The rotating magnetron sputtering target and the corresponding magnetron sputtering device of the present invention improve the plasma density within a coating region, so that it forms a film with better quality and better uniformity.

### FIELD OF THE INVENTION

The present invention relates to the field of thin-film deposition, and more particularly to a rotating magnetron sputtering target and a corresponding magnetron sputtering device which can markedly improve the plasma density within a coating region.

### BACKGROUND OF THE INVENTION

Because of the uniform surface etching, the rotating magnetron sputtering target has higher utilization rate (more than 70%); meantime, the higher thin-film uniformity and the rotating sputtering characteristic can well eliminate common defects of the flat target, such as arc striking.

A common rotating magnetron sputtering target is shown in FIG. 1, which is a structural schematic view of a traditional rotating magnetron sputtering target, wherein the rotating magnetron sputtering target comprises a pole shoe 11, a plurality of magnetrons 12 and a target 13. The target 13 is a hollow cylinder, wherein the pole shoe 11 and the magnetrons 12 are arranged therein. The magnetron 12 comprises a north (N) pole and a south (S) pole arranged on both sides, wherein the N pole and the S pole generate balanced magnetic field as shown in FIG. 1. The plasma generated from glow discharge is bound around the target 13 by the balanced magnetic field and bombards the target 13 under the effect of the electric field.

However, the traditional rotating magnetron sputtering target has following defects:

(1) The plasma generated from glow discharge is merely bound around the target 13, and the plasma density is significantly reduced at the farther side of the target 13, so that the energy of target atoms generated from the plasma bombardment is lower (i.e. the plasma density within the coating region is lower) when arriving the coating region on the substrate, which is not sufficient to form a denser film, thus it results in a coarser surface which is adverse to the subsequent process.

(2) at the same time, the plasma is merely bound around the target 13 by the balanced magnetic field, which narrows the regulating range of distance between the target 13 and the substrate, so that it might affect the film uniformity.

Therefore, it is necessary to provide a rotating magnetron sputtering target and a magnetron sputtering device to solve the problems of traditional technology.

### SUMMARY OF THE INVENTION

The object of the present invention is to provide a rotating magnetron sputtering target and a magnetron sputtering device. The rotating magnetron sputtering target has an unbalanced closed magnetic field which increases the plasma density within the coating region and forms a film with better quality and better uniformity, so that it solves the problems of lower plasma density within the coating region on the substrate of the traditional magnetron sputtering device, resulting in a coarser film with uncontrollable uniformity.

In order to solve the above-mentioned problems, the present invention provides technical solutions, as follows:

The present invention relates to a rotary magnetron sputtering target, comprising: a cylindrical target having a receiving space therein; a pole shoe arranged in the receiving space; a plurality of magnetrons embedded in the external surface of the pole shoe along the axial direction of the cylindrical target, comprising a first magnetic pole arranged on a central portion thereof and two second magnetic poles arranged on both sides thereof, wherein the first and the second magnetic poles have opposite polarities; the magnetic force of the second magnetic pole is stronger than the magnetic force of the first magnetic pole; and the polarity of the second magnetic poles of the adjacent magnetrons is opposite to each other.

In the rotating magnetron sputtering target of the present invention, the pole shoe is a cylinder or a regular prism.

In the rotating magnetron sputtering target of the present invention, the pole shoe and the cylindrical target have a common axis.

In the rotating magnetron sputtering target of the present invention, the rotating magnetron sputtering target comprises at least four of the magnetrons which are evenly embedded in the entire external surface of the pole shoe.

In the rotating magnetron sputtering target of the present invention, the rotating magnetron sputtering target comprises six of the magnetrons which are evenly embedded in the entire external surface of the pole shoe.

The present invention further relates to a rotating magnetron sputtering target, comprising: a cylindrical target having a receiving space therein; a pole shoe arranged in the receiving space; a plurality of magnetrons embedded in the external surface of the pole shoe along the axial direction of the cylindrical target, comprising a first magnetic pole arranged on a central portion thereof and two second magnetic poles arranged on both sides thereof, wherein the first and the second magnetic poles have opposite polarities.

In the rotating magnetron sputtering target of the present invention, the magnetic force of the second magnetic pole is stronger than the magnetic force of the first magnetic pole.

In the rotating magnetron sputtering target of the present invention, the polarity of the second magnetic poles of the adjacent magnetrons is opposite to each other.

In the rotating magnetron sputtering target of the present invention, the pole shoe is a cylinder or a regular prism.

In the rotating magnetron sputtering target of the present invention, the pole shoe and the cylindrical target have a common axis.

In the rotating magnetron sputtering target of the present invention, the rotating magnetron sputtering target comprises at least four of the magnetrons which are evenly embedded in the entire external surface of the pole shoe.

In the rotating magnetron sputtering target of the present invention, the rotating magnetron sputtering target comprises six of the magnetrons which evenly are embedded in the entire external surface of the pole shoe.

The present invention further relates to a magnetron sputtering device, comprising: a shield having a sputtering opening; a substrate arranged on the sputtering opening and used to deposit a coating material; and a rotating magnetron sputtering target arranged in a chamber formed by the shield and the substrate, and comprising: a cylindrical target having a receiving space therein; a pole shoe arranged in the receiving space; a plurality of magnetrons embedded in the external surface of the pole shoe along the axial direction of the cylindrical target, and comprising a first magnetic pole arranged on a central portion thereof and two second magnetic poles arranged on both sides thereof, wherein the first and the second magnetic poles have opposite polarities.

In the magnetron sputtering device of the present invention, the magnetic force of the second magnetic pole is stronger than the magnetic force of the first magnetic pole.

In the magnetron sputtering device of the present invention, the polarity of the second magnetic poles of the adjacent magnetrons is opposite to each other.

In the magnetron sputtering device of the present invention, the pole shoe is a cylinder or a regular prism.

In the magnetron sputtering device of the present invention, the pole shoe and the cylindrical target have a common axis.

In the magnetron sputtering device of the present invention, the rotating magnetron sputtering target comprises at least four of the magnetrons which are evenly embedded in the entire external surface of the pole shoe.

In the magnetron sputtering device of the present invention, the rotating magnetron sputtering target comprises six of the magnetrons which are evenly embedded in the entire external surface of the pole shoe.

Compared to the traditional rotating magnetron sputtering target and the magnetron sputter device, the rotating magnetron sputtering of the present invention has an unbalanced closed magnetic field which increases the plasma density within the coating region and forms the film with better quality and better uniformity, so that it solves the problems of lower plasma density within the coating region on the substrate of the traditional magnetron sputtering device, resulting in a coarser film with uncontrollable uniformity.

For the present invention described above will be more apparent, the following specific preferable embodiment with the companying drawings will be elaborated as follows:

### DESCRIPTION OF THE DRAWINGS

FIG. 1 is a structural schematic view of a traditional rotating magnetron sputtering target; and

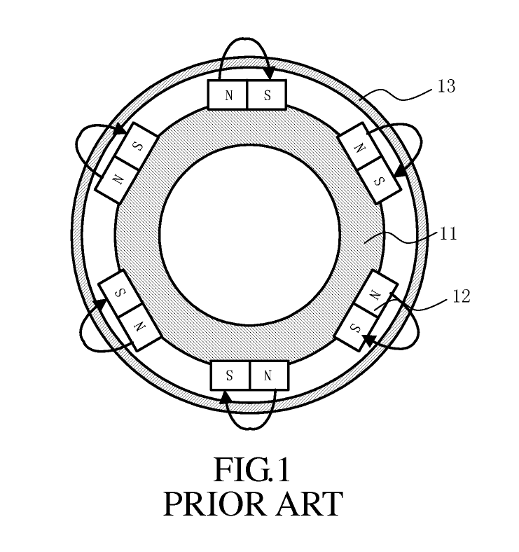

FIG. 2 is a structural schematic view of a preferred embodiment of a magnetron sputtering device in the present invention.

Wherein the reference numbers are illustrated as follows:

21. shield;

22. substrate;

23. rotating magnetron sputtering target;

231. cylindrical target;

232. pole shoe;

233. magnetron;

2331. N-S-N magnetron;

2332. S-N-S magnetron.

### DETAILED DESCRIPTION OF THE PREFERRED EMBODIMENTS

The structure and the technical means adopted by the present invention to achieve the above and other objects can be best understood by referring to the following detailed description of the preferred embodiments and the accompanying drawings. Furthermore, directional terms described by the present invention, such as upper, lower, front, back, left, right, inner, outer, side, longitudinal/vertical, transverse/horizontal, and etc., are only directions by referring to the accompanying drawings. Therefore, the used directional terms are used to describe and understand the present invention, but the present invention is not limited thereto.

In figures, the similar structural units are designated by the same reference numbers.

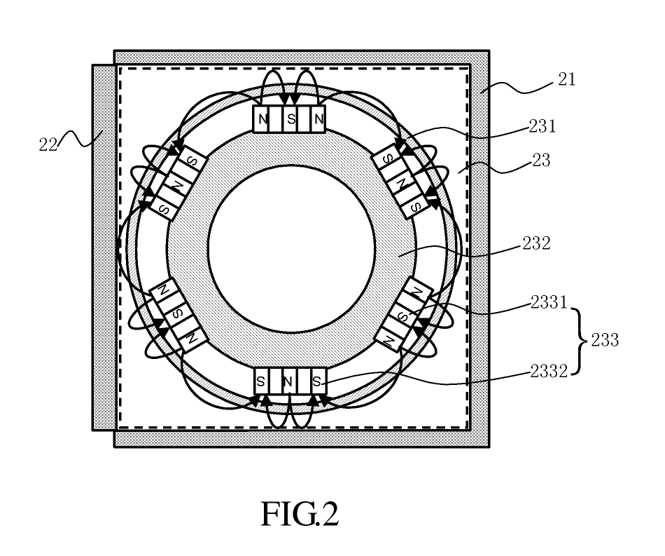

Please refer to FIG. 2, a structural schematic view of a preferred embodiment of a magnetron sputtering device in the present invention is illustrated. The magnetron sputtering device comprises a shield 21, a substrate 22 and a rotating magnetron sputtering target 23; the shield 21 has a sputtering opening. The substrate 22 is arranged on the sputtering opening and used to deposit a coating material. The rotating magnetron sputtering target 23 is arranged in a chamber formed by the shield 21 and the substrate 23, comprising a cylindrical target 231, a pole shoe 232 and a plurality of magnetrons 233; the cylindrical target 231 is hollow and has a receiving space inside. The pole shoe 232 is arranged in the receiving space. Preferably, the pole shoe 232 is a cylinder or a regular prism, so as to obtain a better magnetic field shape, thus the cylindrical target 231 and the pole shoe 232 have a common axis.

Six of the magnetrons 233 are evenly embedded in the external surface of the pole shoe 232 along the axial direction of the cylindrical target 231, and each of the magnetrons 233 comprises a fist magnetic pole and two second magnetic poles. The first magnetic pole is arranged on a central portion of the magnetron 233 along the axial direction of the cylindrical target 231, and the second magnetic poles are arranged on both sides of the magnetron 233 along the axial direction of the cylindrical target 231. The first and the second magnetic pole have opposite polarities: the first magnetic pole is a N pole and the second magnetic pole is a S pole, or the first magnetic pole is a S pole and the second magnetic pole is a N pole. Therefore, it constitutes N-S-N magnetrons 2331 and S-N-S magnetrons 2332 as shown in the figure.

In this embodiment, the magnetic force (the magnetic pole intensity or magnetic flux through the second magnetic pole) of the second magnetic pole is stronger than the magnetic force (the magnetic pole intensity or magnetic flux through the first magnetic pole) of the first magnetic pole, that is, in the N-S-N magnetron 2331, the magnetic force of the N pole is stronger than the magnetic force of the S pole, and in the S-N-S magnetron 2332, the magnetic force of the S pole is stronger than the magnetic force of the N pole. The polarity of the second magnetic pole of the magnetron 233 is opposite to the adjacent one, in other words, what adjacent to the N-S-N magnetron 2331 are S-N-S magnetrons 2332, and the N-S-N magnetrons 2331 and the S-N-S magnetrons 2332 are arranged in turn on the external surface of the pole shoe 232. Accordingly, each of the magnetrons 233 forms an unbalanced closed magnetic field, and each of the magnetrons 233 forms a balanced magnetic field (i.e., each of the magnetrons 233 must have magnetic field lines extending to the adjacent magnetron 233 so as to form a closed magnetic field) with the adjacent magnetron 233, which increases the magnetic field intensity between the magnetrons 233 and the high-density plasma region in the chamber of the magnetron sputtering device.

In this embodiment, the rotating magnetron sputtering target 23 comprises six of the above-mentioned magnetrons 233 which are evenly embedded in the entire external surface of the pole shoe 233; that is to say, the connecting lines between each cross-sectional center of magnetrons 233 and the cross-sectional center of the shoe pole 232 reveal 60°. Hence, it guarantees the uniformity of the magnetic field, generated from the magnetrons 233, of the cylindrical target 231, which results in a uniform plasma bombardment to the cylindrical target 231, which guarantees that the sputtering target atoms form a uniform thin-film on the substrate 22. Surely, according to the practical situation, it is also allowable to arrange only four of the magnetrons 233 which are evenly embedded in the entire external surface of the pole shoe 232. If four of the magnetrons 233 are designated, the connecting lines between each cross-sectional center of magnetrons 233 and the cross-sectional center of the shoe pole 232 reveal 90°.

When the magnetron sputtering device of the present invention is used, orthogonal magnetic field and electric field are added between the rotating magnetron sputtering target 23 used as a cathode and the substrate 22 used as an anode; then inert gas (usually argon) is filled into the chamber formed by the shield 21 and the substrate 22. Under the effect of the electric field, argon gas is ionized into argon ions with positive charges and electrons. Argon ions accelerate to bombard the cylindrical target 231 under the effect of the electric field, sputtering a plenty of neutral target atoms deposited on the substrate 22 to from the thin-film; meanwhile, argon ions release secondary electrons when bombarding the cylindrical target 231; the secondary electrons are influenced by Lorentz force during the process of accelerating to the substrate 22 and are bound around the region within high-density plasma density on the surface of the cylindrical target 231. Since each of the magnetrons 233 forms an unbalanced closed magnetic field, on the basis of the traditional rotating magnetron sputtering target, through changing the magnetic field distribution, the N and S poles are certain to efficiently bind the sputtering secondary electrons on the traverse magnetic field which is generated from the cylindrical target 231 and parallel to the target surface, so as to maintain the stable magnetron sputtering discharge; meanwhile, another part of electrons escape from the region of the cylindrical target 231 under the effect of the longitudinal magnetic field which is generated from the N and S poles and perpendicular to the target surface, moving to the coating region on the substrate 22. The electrons moving to the substrate 22 collide the neutral target atoms and further increase the plasma density within the coating region on the substrate 22.

Therefore, the magnetron sputtering device of the present invention can improve the magnetic field distribution of the target surface of the cylindrical target 231, so that it better binds the sputtering secondary electrons and increases the sputtering efficiency and ionization rate; meanwhile, it can further increase the energy of escaping secondary electrons and markedly increase the plasma density within the coating region on the substrate 22, resulting in faster film forming speed within the coating region, better electric property and thin-film crystallinity, smoother thin-film surface, and better uniformity; besides, because of the arrangement of the unbalanced closed magnetic field of the magnetron 233, the high-density plasma region and the regulating range of distance between the target 13 and the substrate 22 are expanded, which advantageously guarantees the thin-film uniformity, crystallinity and surface roughness.

The effective magnetic field range of the magnetron sputtering device of the present invention measured by Gauss meter is 60%-100% is larger than the effective magnetic field range of the traditional sputtering device. The plasma density within the coating region on the substrate 22 increases 20%-40%; meanwhile, the thickness heterogeneity of the thin-film is less than 4%, and the heterogeneity of the electric performance is less than 3%.

The rotating magnetron sputtering target and the magnetron sputtering device of the present invention have unbalanced closed magnetic field which improves the magnetic field distribution of the target surface of the cylindrical target and increases the plasma density within the coating region, forming the film with better quality and better uniformity, so that it solves the problems of lower plasma density within the coating region on the substrate of the traditional magnetron sputtering device, resulting in a coarser film with uncontrollable uniformity.

The present invention has been described with a preferred embodiment thereof and it is understood that many changes and modifications to the described embodiment can be carried out without departing from the scope and the spirit of the invention that is intended to be limited only by the appended claims.

What is claimed is:

1. A rotating magnetron sputtering target, comprising:
a cylindrical target having a receiving space therein;
a pole shoe arranged in the receiving space;
a plurality of magnetrons embedded in an external surface of the pole shoe along an axial direction of the cylindrical target, and comprising a first magnetic pole arranged on a central portion thereof and two second magnetic poles arranged on both sides thereof, wherein the first and the second magnetic poles have opposite polarities;
wherein the magnetic force of the second magnetic pole is stronger than the magnetic force of the first magnetic pole; and
wherein the polarity of the second magnetic poles of the adjacent magnetrons is opposite to each other.

2. The rotating magnetron sputtering target according to claim 1, wherein the pole shoe is a cylinder or a regular prism.

3. The rotating magnetron sputtering target according to claim 2, wherein the pole shoe and the cylindrical target have a common axis.

4. The rotating magnetron sputtering target according to claim 1, wherein the rotating magnetron sputtering target comprises at least four of the magnetrons which are evenly embedded in the entire external surface of the pole shoe.

5. The rotating magnetron sputtering target according to claim 4, wherein the rotating magnetron sputtering target comprises six of the magnetrons which are evenly embedded in the entire external surface of the pole shoe.

6. A rotating magnetron sputtering target, comprising:
a cylindrical target having a receiving space therein;
a pole shoe arranged in the receiving space; and
a plurality of magnetrons embedded in an external surface of the pole shoe along an axial direction of the cylindrical target, and comprising a first magnetic pole arranged on a central portion thereof and two second magnetic poles arranged on both sides thereof, wherein the first and the second magnetic poles have opposite polarities.

7. The rotating magnetron sputtering target according to claim 6, wherein the magnetic force of the second magnetic pole is stronger than the magnetic force of the first magnetic pole.

8. The rotating magnetron sputtering target according to claim 6, wherein the polarity of the second magnetic poles of the adjacent magnetrons is opposite to each other.

9. The rotating magnetron sputtering target according to claim 6, wherein the pole shoe is a cylinder or a regular prism.

10. The rotating magnetron sputtering target according to claim 9, wherein the pole shoe and the cylindrical target have a common axis.

11. The rotating magnetron sputtering target according to claim 6, wherein the rotating magnetron sputtering target comprises at least four of the magnetrons which are evenly embedded in the entire external surface of the pole shoe.

12. The rotating magnetron sputtering target according to claim 11, wherein the rotating magnetron sputtering target comprises six of the magnetrons which are evenly embedded in the entire external surface of the pole shoe.

13. A magnetron sputtering device, comprising:
a shield having a sputtering opening;
a substrate arranged on the sputtering opening and used to deposit a coating material; and
a rotating magnetron sputtering target arranged in a chamber formed by the shield and the substrate, and comprising:
a cylindrical target having a receiving space therein;
a pole shoe arranged in the receiving space;
a plurality of magnetrons embedded in an external surface of the pole shoe along an axial direction of the cylindrical target, and comprising a first magnetic pole arranged on a central portion thereof and two second magnetic poles arranged on both sides thereof, wherein the first and the second magnetic poles have opposite polarities.

14. The magnetron sputtering device according to claim 13, wherein the magnetic force of the second magnetic pole is stronger than the magnetic force of the first magnetic pole.

15. The magnetron sputtering device according to claim 13, wherein the polarity of the second magnetic poles of the adjacent magnetrons is opposite to each other.

16. The magnetron sputtering device according to claim 13, wherein the pole shoe is a cylinder or a regular prism.

17. The magnetron sputtering device according to claim 16, wherein the pole shoe and the cylindrical target have a common axis.

18. The magnetron sputtering device according to claim 13, wherein the rotating magnetron sputtering target comprises at least four of the magnetrons which are evenly embedded in the entire external surface of the pole shoe.

19. The magnetron sputtering device according to claim 18, wherein the rotating magnetron sputtering target comprises six of the magnetrons which are evenly embedded in the entire external surface of the pole shoe.
